(19) United States
(12) Patent Application Publication
(10) Pub. No.: US 2007/0052468 A1
(43) Pub. Date: Mar. 8, 2007

(54) Shift down level shifter

(75) Inventors: Chun Shiah, Hsinchu (TW); Chun-Peng Wu, Hsinchu (TW)

Correspondence Address: STEPHEN B. ACKERMAN, 28 DAVIS AVENUE, POUGHKEEPSIE, NY, 12603, US

(73) Assignee: Etron Technology, Inc.

(21) Appl. No.: 11/219,465

(22) Filed: Sep. 2, 2005

(51) Int. Cl. H03L 5/00

(52) U.S. Cl. 327/333

(57) ABSTRACT

A shift down-level shifter used with a memory negative word line architecture prevents current flow between a positive bias voltage and a negative bias voltage when the input signal is at circuit ground. The output circuit of the shift down-level shifter comprises two transistors connecting a positive voltage and a negative voltage to the output terminal. A feed back circuit establishes a node voltage from which the output transistor coupling the negative voltage to the output terminal is controlled to be off when the input signal is at circuit ground and the output is a positive voltage, thus preventing current flow between the positive and negative bias voltages, which reduces power consumption.

### BACKGROUND OF THE INVENTION

1. Field of Invention

The present invention is related to integrated circuits and in particular to a shift down-level shifter used to provide a negative voltage to memories having a negative word line architecture.

2. Description of Related Art

In memories with a negative word line architecture an inverter circuit is used to provide a negative voltage to a memory word line. When a positive voltage is applied to the input of the inverter circuit the output transistor coupled to a negative bias voltage is turned on supplying a negative voltage to the output of the inverter circuit. When the input signal is at a circuit ground the output transistor coupled to a positive supply voltage is turned on supplying a positive voltage to the output, but the output transistor coupled to the negative supply voltage is not turned off, which allows current to flow between the positive and negative supply voltages causing an increase in power consumption.

In U.S. Pat. No. 6,819,159 (Lencioni) a level shifter circuit is directed to a first and second level shifting circuitry providing an output and a complimentary output. U.S. Pat. No. 6,788,125 (Tomsio) is directed to a level shifter circuit for converting voltage levels of signals in CMOS devices and consumes less power and requires less area than previous level shifter designs. U.S. Pat. No. 6,477,092 (Tankano) is directed to a level shifter circuit containing a first and second portion in which the first portion produces a first and a second potential, lower than the first potential, and the second portion produces a third potential lower than the second potential. U.S. Pat. No. 5,723,986 (Nakashiro et al.) is directed to a level shifter circuit having two portions where the first portion produces a high voltage between a first and second voltage, and the second portion produces a low voltage between a third and a fourth voltage that are lower than the first and second voltage. U.S. Pat. No. 5,450,357 (Coffman) is directed to a level shifter circuit connected between a high voltage source and a low voltage source. Depending upon the input signal, the high voltage source or the low voltage source is connected to the output of the level shifter circuit.

In FIG. 1A is shown a down-level shifter of prior art. A P-channel transistor 10 and an N-channel transistor 11 are coupled together to form an output Vout of the down-level shifter circuit. The gates of both transistors 10 and 11 are coupled to an input voltage Vin. As graphically shown in FIG. 1B, the N-channel transistor 11 is turned on when the input voltage Vin=Vcc connecting the negative bias Vlow to the output Vout, and the P-channel transistor 10 is turned off. The P-channel transistor 10 is turned on when Vin=Vss (circuit ground) connecting the positive bias voltage Vcc to the output Vout; however, Vin=Vss is still a positive voltage relative to Vlow and the N-channel transistor 11 conducts a current Idc adding to the power consumption of the memory chip upon which the down-level shifter resides.

### SUMMARY OF THE INVENTION

It is an objective of the present invention to prevent current flow between a positive voltage bias and a negative voltage bias of a down-level shifter circuit.

It is also an objective of the present invention to turn off the output transistor supplying a negative voltage to an output of a down-level shifter circuit when the input signal is at circuit ground.

It is still an objective of the present invention to feed back to an input portion of a down-level shifter circuit and creating a node voltage from which the output transistor supplying the negative voltage to the output is controlled off when the input signal to the down-level shifter is at circuit ground.

### BRIEF DESCRIPTION OF THE DRAWINGS

This invention will be described with reference to the accompanying drawings, wherein:

FIG. 1A is a circuit diagram for a down-level shifter circuit of prior art;

FIG. 1B is a voltage diagram for the circuit of FIG. 1A of prior art;

FIG. 2A is a circuit diagram of the down-level shifter circuit of the present invention;

FIG. 2B is a voltage diagram of the present invention for the circuit of FIG. 2A; and

FIG. 3 Is a method diagram of the present invention for preventing current flow between a positive voltage bias and a negative voltage bias.

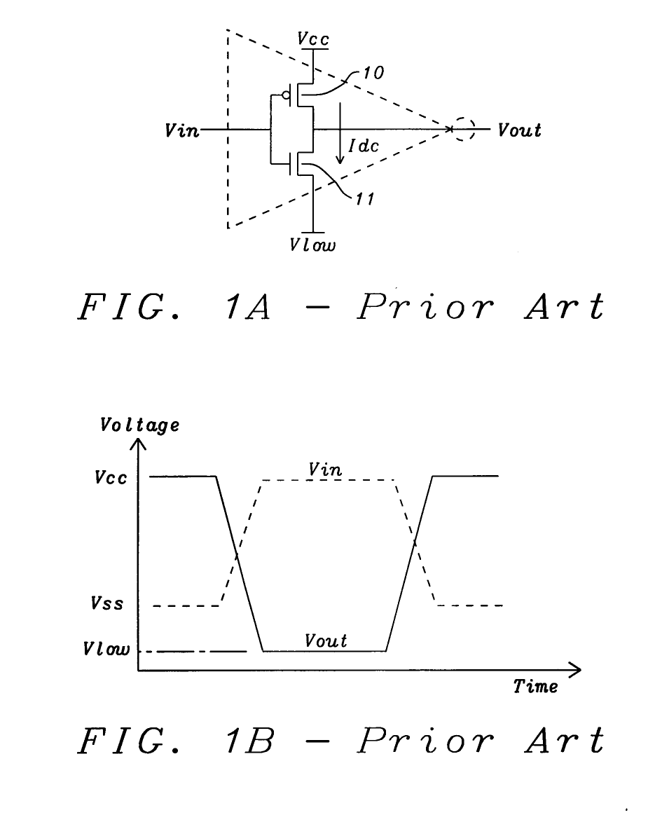

### DETAILED DESCRIPTION OF THE PREFERRED EMBODIMENT

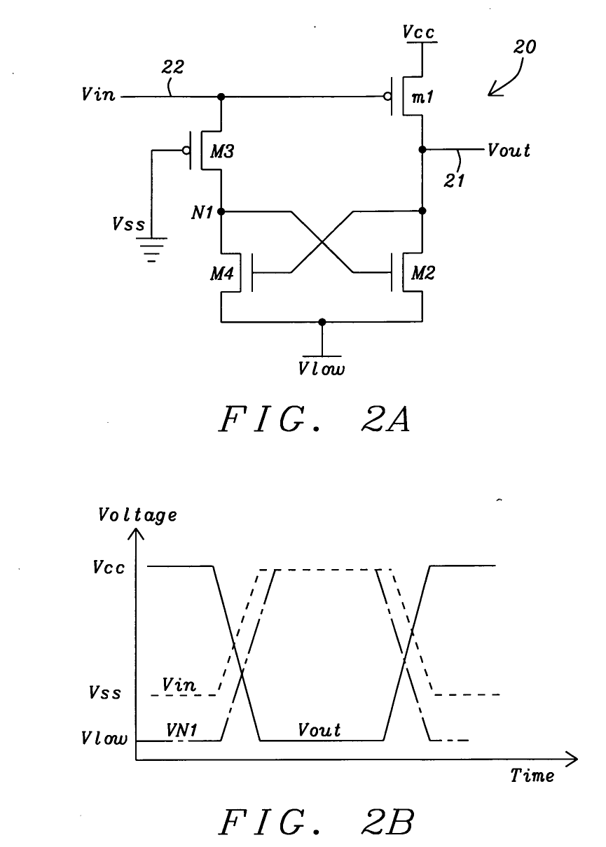

In FIG. 2A is shown a circuit diagram of the present invention in which a down-level shifter circuit 20 is biased between a positive voltage Vcc and a negative voltage Vlow. The output 21 of the down-level shifter circuit is formed by the connection between a P-channel transistor M1 and an N-channel transistor M2 producing an output voltage Vout. An input portion of the down-level shifter circuit is formed by a P-channel transistor M3 and an N-channel transistor M4.

The input 22 of the down-level shifter circuit 20 is connected the gate of the P-channel transistor M1 and the source of P-channel transistor M3. The gate of transistor M3 is connected to circuit ground Vss, and the connection of M3 and M4 forms a node N1. Transistors M2 and M4 are biased with the negative bias voltage Vlow. Transistors M2 and M4 are connected in a bi-stable arrangement where the gate of M2 is connected to the node N1 and the gate of M4 is connected to the output 21 of the down-level shifter circuit 20.

Viewing FIG. 2B along with FIG. 2A, when the input voltage Vin=Vss the output voltage Vout=Vcc. Transistor M4 is turned on since the gate of M4 is connected to the output 21 where Vout=Vcc. The voltage VN1 at node N1 is VN1=Vlow, which is applied to the gate of M2 turning off M2 and isolating the output from the negative bias Vlow. Transistor M3 is also turned off because VN1=Vlow<Vss. This prevents current flow between Vcc and Vlow at the output 21 and current to flow between the input 22 and Vlow.

When the input voltage Vin=Vcc, M1 is turned off and M3 is turned on. The node N1 raises to Vcc and transistor M2 connected to Node 1 is turned on allowing the output 21 to become a negative voltage Vlow. Transistor M4 is turned off by the gate connection to the output 21 when Vout=Vlow. Again no current flows between Vcc and Vlow since transistor M1 is off.

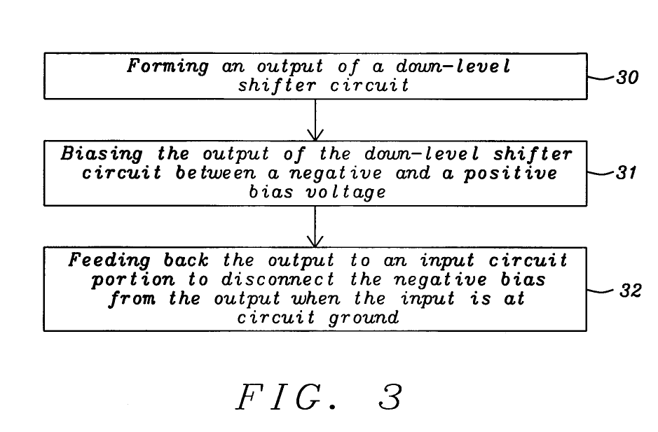

In FIG. 3 is shown a flow diagram of the present invention for preventing current flow between the positive voltage bias and the negative voltage bias of the down-level shifter circuit. An output circuit portion of the down-level shifter is formed 30 to produce an output voltage Vout. The output circuit portion of the down-level shifter circuit is biased between a positive voltage and a negative voltage 31. The output voltage is fed back to an input circuit portion to disconnect the negative voltage bias from the output when the input to the down-level shifter circuit is at circuit ground potential and the output is at the positive voltage 32; therefore, preventing current to flow between the positive voltage bias and the negative voltage bias and reducing power consumption.

The output circuit portion is formed by a first transistor and a second transistor connected in series and producing an output at the connection between the first and second transistors. The first transistor is biased with a positive voltage and the second transistor is biased with a negative voltage. The input to the down-level shifter circuit is coupled to a gate of the first transistor and a source of a third transistor that has a gate biased to circuit ground. The third transistor is further connected to a fourth transistor in which the connection forms a node that is connected to the gate of the second transistor. The fourth transistor is biased with the negative voltage causing the voltage at the node to be negative when the circuit input is at circuit ground and the output voltage is at the positive voltage. The node controls the gate of the second transistor, and turns off the second transistor when negative and prevents current flow from the positive bias voltage to the negative bias voltage. The gate of the fourth transistor is controlled by the down-level circuit output voltage. When the output voltage is positive the fourth transistor is turned on and the-negative voltage is connected to the node. When the output voltage is negative, the fourth transistor is turned off and the node voltage is positive turning on the second transistor.

While the invention has been particularly shown and described with reference to preferred embodiments thereof, it will be understood by those skilled in the art that various changes in form and details may be made without departing from the spirit and scope of the invention.

What is claimed is:

1. A shift down level shifter circuit, comprising:
a) an inverter circuit biased between a positive voltage and a negative voltage;
b) an output of said inverter circuit producing said positive voltage when an input of said inverter circuit is at a circuit ground voltage, and said output producing said negative voltage when the input is at said positive voltage; and
c) a feedback circuit preventing current flow between said positive and negative voltages when said input of said inverter circuit is at said circuit ground voltage and the output of said inverter circuit is at said positive voltage.

2. The circuit of claim 1, wherein said inverter circuit further comprises:
a) a first transistor biased to said positive voltage coupled at said output to a second transistor biased to a negative voltage;
b) a third transistor coupled to said input with a gate of said third transistor connected to circuit ground;
c) a fourth transistor biased with said negative voltage and coupled to said third transistor to form a node that is coupled to said gate of the second transistor; and
d) said gate of the fourth transistor coupled to said output.

3. The circuit of claim 2, wherein said node is at said negative voltage when the input of the inverter circuit is at or near the circuit ground voltage, thereby controlling said second transistor to be off and preventing current flow between the positive and negative voltages.

4. The circuit of claim 2, wherein said node is at said positive voltage when said input is at said positive voltage, thereby controlling said second transistor to be on and couple said negative voltage to said output.

5. The circuit of claim 2, wherein said first and third transistors are P-channel transistors and said second and fourth transistors are N-channel transistors.

6. The circuit of claim 1, wherein said feedback circuit is formed by a bi-stable circuit coupled to said output and said input.

7. A method of forming a down level shifter circuit to prevent current flow between a positive and negative voltage biases, comprising:
a) forming an output of a shifter circuit;
b) biasing said output of the shifter circuit between a positive voltage and a negative voltage; and
c) feeding back said output to an input circuit portion to disconnect said negative voltage from said output when an input voltage to said shifter circuit is at circuit ground and said output is at said positive voltage.

8. The method of claim 7, wherein said shifter circuit further comprises:
a) forming said output from a connection of a first transistor biased to said positive voltage to a second transistor biased to said negative voltage;
b) coupling an input of said shifter circuit to said first transistor and a third transistor in which a gate of said third transistor is biased to circuit ground;
c) forming a voltage node with said connection between said third transistor and a fourth transistor;
d) biasing said fourth transistor with said negative voltage;
e) controlling said gate of the second transistor with said voltage node; and
f) controlling said gate of the fourth transistor with said output.

9. The method of claim 8, wherein controlling said gate of the second transistor turns off the second transistor blocking current flow between the positive and negative voltages when said input is at circuit ground and said output is at said positive voltage.

10. The method of claim 8, wherein controlling said gate of the fourth transistor with the output when the input is at the positive voltage turns on said second transistor connecting said negative voltage to the output.

11. The method of claim 8, wherein said first and third transistors are P-channel transistors and said second and fourth transistors are N-channel transistors.

12. The method of claim 7, wherein feeding back said output to said input circuit portion connects said negative voltage to the output when said input voltage is the positive voltage.

13. A shifter circuit, comprising:
a) a means for forming a down level shifter circuit between a positive voltage bias and a negative voltage bias;
b) a means for producing said positive voltage at an output of said shifter circuit when an input is at circuit ground;
c) a means for producing said negative voltage at said output of the shifter circuit when said input is a positive voltage; and
d) a means for blocking current flow between the positive voltage and negative voltage bias.

14. The circuit of claim 13, wherein said means for blocking current flow between the positive and negative voltage bias is formed by a means to feedback said output to an input circuit and a means to form a node voltage in said input circuit from which said node voltage turns off a transistor device coupling said negative voltage bias to said output.

15. The circuit of claim 14, wherein said means to form said node voltage turns on said transistor device to produce said negative voltage at the output when said input is said positive voltage.
